(19) United States
(12) Patent Application Publication
(10) Pub. No.: US 2014/0116497 A1
(43) Pub. Date: May 1, 2014

(54) Building Integrated Solar Aperture Fixtures

(71) Applicant: Wyatt Sanders, Jacksonville, FL (US)

(72) Inventor: Wyatt Sanders, Jacksonville, FL (US)

(21) Appl. No.: 14/063,297

(22) Filed: Oct. 25, 2013

Related U.S. Application Data
(60) Provisional application No. 61/720,573, filed on Oct. 31, 2012.

(51) Int. Cl. H01L 31/042; E06B 9/38

(52) U.S. Cl. CPC H01L 31/0422; E06B 9/38
USPC 136/246

(57) ABSTRACT

Systems and apparatus which provide onsite electrical power which has been generated by solar energy are disclosed. In an aspect, an onsite solar power generation apparatus is configured as an interior window covering. The power generation apparatus comprises a frame, a plurality of movable cross members, a plurality of photovoltaic cells, a conversion component, and an AC power plug. In particular, systems and apparatus in accordance with the present disclosure may be configured for ease of installation by laymen and be self-contained (i.e., requiring installation of one assembly of equipment and connecting to a building's existing electrical grid via a standard AC power plug and building receptacle).

### CROSS-REFERENCE TO RELATED APPLICATION

This application claims the benefit of U.S. Provisional Patent Application No. 61/720,573, filed Oct. 31, 2012, and entitled “Building Integrated Solar Aperture Fixtures”, the entire contents of which is incorporated herein by reference.

### FIELD OF THE DISCLOSURE

The present invention is generally related to the field electricity generation. More particularly the invention is related to systems and apparatus which may be integrated into a building and facilitate solar energy-based generation of electricity.

### BACKGROUND

The statements in this section merely provide background information related to the present disclosure and may not constitute prior art.

The dramatic increase in energy consumption throughout the 20^{th} century, combined with rising energy costs (especially during peak domestic usage times) has prompted investigation and research into alternative sources of energy. Additionally, inherent losses in transmitting power over long distances make onsite or near-site power generation attractive.

Alternative sources of energy include radiant energy such as light or heat energy. Various attempts to harness the spectrum of radiant energy and convert it into electrical energy has spawned an industry focused on building apparatuses and devices that best capture the radiant energy from the sun which has led to the current state of the art in photovoltaics and thermoelectrics. In practice, the collection of alternative sources of energy to supplement and reduce a residential, commercial, or public subscriber's utility usage provides a cost effective energy strategy.

Thermoelectric generators convert differences in temperature or heat energy to electrical energy. Photovoltaic devices convert light energy to electrical energy. This is accomplished by solar cells also called photovoltaic cells typically made of, but not limited to, a light absorbing material such as microcrystalline, polycrystalline, or amorphous silicon that absorbs light energy, generating excitons, thereby separating charge carriers to an external circuit which is then merged into the main electrical grid using inverters or in the alternative, batteries for operation of stand-alone systems and devices.

Utilization of radiant energy via, for example, photovoltaic technology or thermoelectric technology has been developed and enables onsite generation of electricity.

For example, electricity generating solar panels may be placed on the roof of a residential home, or commercial building, and connected to the building's or the municipal power grid, thereby providing electricity for use in the home. Such electricity generation may be more cost effective on a kilowatt hour basis than electricity supplied by municipal power grids during peak usage.

One drawback of traditional solar panel installations is difficulty of installation. Large panels weighing several hundred pounds must be transported to the roof of a home via crane or by the efforts of several workers. These panels must then be bolted to the roof and connected to an inverter or other set of electrical components in order to provide power to the home. The inverter is typically a large unit placed inside the building (e.g., in the garage) or mounted on an exterior wall of the building and is electrically connected to the building's power grid.

In addition to comprising several components which must be installed separately and interconnected, traditional roof-mounted solar panel installations require a professional to install and connect them.

Roof-mounted solar panels or other solar panels positioned outside face design constraints as well. Such panels must be engineering to withstand rain, humidity and pollutants in the outside air, and temperatures which vary significantly over days, months, and years. Due to exposure to the elements, these panels must also be cleaned periodically.

Conventional window treatments such as drapes, louvered shades, venetian blinds, shutters, sliding doors as well as garage doors among other aperture fixtures are primarily used to obstruct the entry of sunlight or access into homes or buildings in order to provide shade to the occupants and protect equipment, devices, apparel, or other items from the harmful rays of the sun. These aperture fixtures simply dissipate light and are not constructed to collect the energy from sunlight in their deployment or feed that energy into the electrical grid embedded in buildings and structures.

Various U.S. patents disclose apparatus which integrate photovoltaic cells into window treatments. For example, U.S. Pat. No. 7,617,857 discloses utilizing a small photovoltaic cell mounted on venetian blind housing to control the amount of light the venetian blinds allow inside. U.S. Pat. No. 4,636,579 discloses utilizing flexible photovoltaic cells to provide window coverings in the form of a retractable window shade. U.S. Pat. No. 4,212,289 discloses a storm shutter system wherein the shutters contain a solar heating system. U.S. Pat. No. 4,137,098 discloses a building-integrated window comprising two plates of glass which encase rotatable photovoltaic cells.

Given the foregoing, systems and apparatus are needed which provide onsite power generation via alternative energy, such as solar power. In particular, systems and apparatus are needed which may be installed and integrated in the power grid of a building by laymen. Additionally, modular systems and apparatus are needed which provide window coverings having integrated photovoltaic cells and inverters, such that the system or apparatus may be installed via placement of a single unit within the building.

### SUMMARY

This Summary is provided to introduce a selection of concepts. These concepts are further described below in the Detailed Description section. This Summary is not intended to identify key features or essential features of this disclosure's subject matter, nor is this Summary intended as an aid in determining the scope of the disclosed subject matter.

Aspects of the present disclosure provide systems and apparatus which provide onsite electrical power which has been generated from solar energy. Such solar power generation apparatus may be installed inside a building (e.g., within a window frame), on a portion of a building (e.g., on an exterior door, on a garage door), or form a portion of the roof or wall of a structure (e.g., a planter). In particular, systems and apparatus in accordance with the present disclosure may be configured for ease of installation by laymen and be self-contained (i.e., requiring installation of one assembly of equipment and connecting to a building's existing electrical grid via a standard AC power plug).

In an aspect, an onsite solar power generation apparatus is configured as an interior window covering. The power generation apparatus comprises a frame, a plurality of movable cross members, a plurality of photovoltaic cells, a microinverter, and an AC power plug.

The power generation apparatus may be removably mounted at a window via the frame. The frame may be installed in the frame of a window via traditional window dressing mounts and techniques, thereby eliminating the need for skilled technicians. The frame is additionally configured to support each of the cross members and the microinverter. The frame electrically connects photovoltaic cells housed by the cross members to the microinverter. The microinverter is housed within the frame (e.g., in the base of the frame). Each cross member is rotatably connected to the frame and comprises at least one photovoltaic cell. Each cross member may also comprise a bypass diode. Each cross member may rotate between a closed position and an open position. In the closed position, the cross members are in a vertical position and form a barrier which prevents light from entering the interior of the building. In the closed position, the photovoltaic cells face outward, thereby receiving sunlight which is converted into electricity. In the open position, the cross members have been rotated away from the window such that light may pass into the building. Cross members may be manually moved between positions or moved with the aid of a mechanical device. The power generation apparatus may comprise a pulley, motor, solenoid actuator or some other device apparent to those having skill in the art after reading the description herein suitable for moving the cross members from a closed position to an open position. In an aspect, bifurcated metal, memory metal, or similar may be used which, in response to a temperature change or voltage change, alters its shape, is connected to a cross member and causes the cross member to move between a closed position and an open position in response to changing environmental conditions, voltage changes, or the like.

The photovoltaic cells are electrically connected to the microinverter, supplying a DC current which the microinverter converts to AC current suitable for powering equipment found in the building or compatible with the building's power grid (e.g., 120 Vac current, 240 Vac). A cable is electrically connected to the microinverter at one end portion and comprises the AC power plug at a second end portion. The AC power plug may be removably connected to a corresponding power receptacle, thereby augmenting the electrical power available to the building without separate, additional equipment.

In an aspect, the frame comprises a track. The frame may be removably attached to an interior wall above a window. In a manner similar to vertical blinds, each cross member is vertically oriented and slidably attached to the frame at the track. Each cross member may rotate between a closed position and an open position along its long axis.

In an aspect, a garage door, or other movable exterior surface, comprises the frame.

In an aspect, the frame is arranged as the roof, wall, or other exterior surface of a planter. In this manner, cross members function as a wall or roof when in the closed position and provide access to the interior of the planter when in the open position.

Further features and advantages of the present disclosure, as well as the structure and operation of various aspects of the present disclosure, are described in detail below with reference to the accompanying drawings.

### BRIEF DESCRIPTION OF THE DRAWINGS

The features and advantages of the present disclosure will become more apparent from the Detailed Description set forth below when taken in conjunction with the drawings in which like reference numbers indicate identical or functionally similar elements.

FIG. 1 is a front perspective view of an onsite solar power generation apparatus configured to be placed adjacent to a building window, according to an aspect of the present disclosure.

FIG. 2 is a rear view of an onsite solar power generation apparatus configured to be placed adjacent to a building window wherein the power generation apparatus comprises a manual mechanism for altering the positioning of the cross members, according to an aspect of the present disclosure.

FIG. 3 is a rear perspective view of an onsite solar power generation apparatus configured to be placed adjacent to a building window, wherein the frame and the mounting plate have been removably connected, according to an aspect of the present disclosure.

FIG. 4 is a front perspective view of an onsite solar power generation apparatus which has been integrated into the roof of a planter, according to an aspect of the present disclosure.

FIG. 5 is a front view of an onsite solar power generation apparatus which may also serve as a garage door, according to an aspect of the present disclosure.

FIG. 6 is a front view of an onsite solar power generation apparatus configured to be placed adjacent to a sliding door or to serve as vertical blinds, according to an aspect of the present disclosure.

FIG. 7 is a front perspective view of an onsite solar power generation apparatus configured to be placed adjacent to a building window, according to an aspect of the present disclosure.

FIGS. 8A-C are front perspective views of an onsite solar power generation apparatus configured to be placed adjacent to a building window depicting the movement of cross members from a closed position to an open position, according to an aspect of the present disclosure.

FIG. 9 is a front perspective view of an onsite solar power generation apparatus configured to be placed adjacent to a building window, according to an aspect of the present disclosure.

FIG. 10 is a front perspective view of an onsite solar power generation apparatus configured to be placed adjacent to a building window, wherein the cross member has been retracted, according to an aspect of the present disclosure.

FIG. 11 is a block diagram of an exemplary system for accessing information regarding an onsite solar power generation apparatus, according to an aspect of the present disclosure.

FIG. 12 is a block diagram of an example computing system useful for implementing the present disclosure.

### DETAILED DESCRIPTION

The present disclosure is directed to systems and apparatus which provide onsite electrical power which has been generated by solar energy. Such solar power generation apparatus may be modular, self-contained, and installed by laymen.

Aspects of the present disclosure provide systems and apparatus which may be installed inside a building (e.g., within a window frame), on a portion of a building (e.g., on an exterior door, on a garage door), or form a portion of the roof of a structure (e.g., a planter) and provide alternating current to a building power grid, alternating current appliances and the like.

Aspects of the present disclosure utilize photovoltaic and/or thermoelectric cells positioned at building apertures including, but not limited to, windows, garage door openings, doors, door frames, sky lights, and the like to convert solar energy to electrical energy. Aspects of the present disclosure utilize one or more solar panels (rigid or flexible) formed from photovoltaic solar cells. Such apparatus may also comprise thermoelectric cells. The fixture is configured to generate electricity and regulate the entrance of light into the building. That is, such apparatus comprise moveable elements which, in the closed position, prevent light from entering the building and in the open position allow light to enter the building.

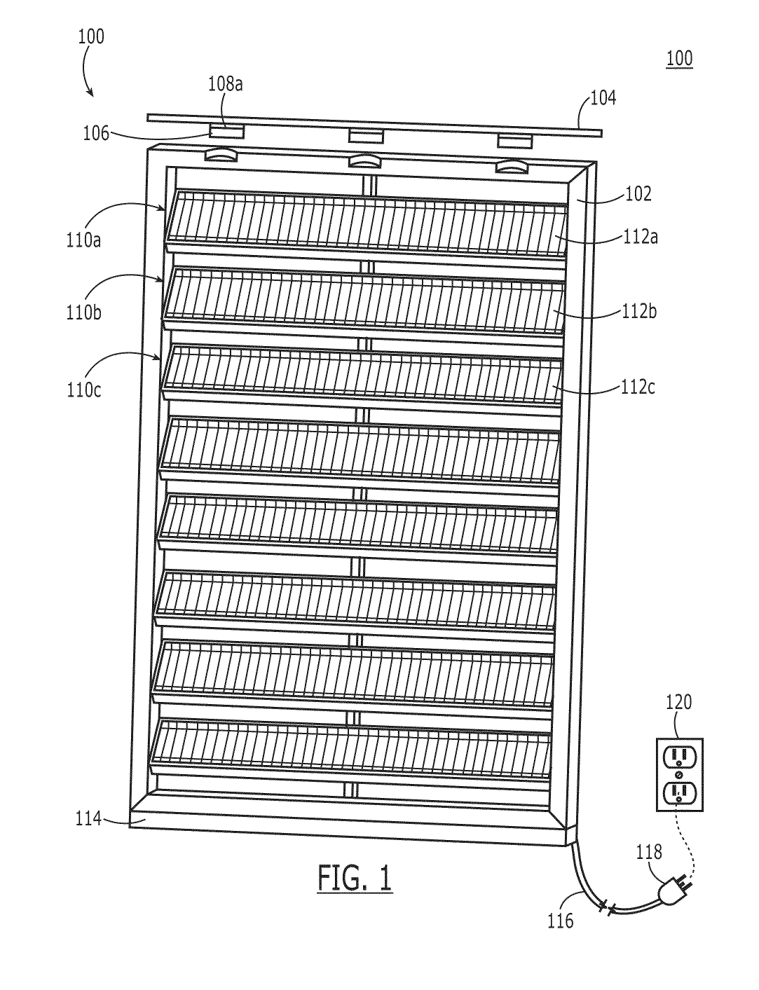

Referring now to FIG. 1, a front perspective view of an onsite solar power generation apparatus 100 configured to be placed adjacent to a building window, according to an aspect of the present disclosure, is shown. The front of power generation apparatus 100 is positioned to face the outside environment, thereby enabling portions of power generation apparatus 100 to receive sunlight which may be converted to electricity.

In an aspect, power generation apparatus 100 is configured as an interior window covering. Power generation apparatus 100 is configured to harness the energy from sunlight that enters through the apertures or other openings in a building (e.g., windows, garages) and back feed that energy into the electrical grid embedded in the building structure for use by appliances and other devices within the structure thus locally producing electrical energy needed to operate the appliances and devices. Power generation apparatus 100 is configured to be self-contained. That is, power generation apparatus 100 contains all the components necessary to capture solar energy and convert it to electrical energy which is then fed into the main electrical grid in the house or other building structure.

Power generation apparatus 100 comprises a frame 102, a plurality of movable cross members 110 (labeled, for clarity, only as cross members 110a-c in FIG. 1), a plurality of solar cells 112 (labeled, for clarity, only as solar cells 112a-c in FIG. 1), a microinverter (not shown) contained within housing 114, and an AC power plug 118.

The power generation apparatus may be removably mounted at a window by connecting frame 102 to mount 104. Mount may be connected to a suitable portion of a building, such as the interior of a window frame. In another aspect, mount 104 may be connected to the building above a window, or adjacent to the window or other desired location in another manner apparent to those skilled in the relevant art(s) after reading the description herein. Generally, frame 102 may be installed in the frame of a window or other building aperture via traditional mounts and techniques, thereby eliminating the need for skilled technicians.

As shown in FIG. 1, mount may comprise male slide connector members 108 (labeled, for clarity, only as male slide connector member 108a in FIG. 1) and frame 102 may comprise slide connector receivers 106 (labeled, for clarity, only as slide connector receiver 106a in FIG. 1). In order to position power generation apparatus 100 over a desired aperture, mount 104 is connected to the building (e.g., by screwing mount 104 into place) and frame 102 is attached by slidably inserting male slide connector members 108 into slide connector receivers 106.

Frame 102 may be configured as a rigid rectangular member. Frame 102 may be constructed from plastic, metal, organic materials or other appropriate materials apparent to those skilled in the relevant art(s) after reading the description herein.

Frame 102 is configured to support each cross member 110 and further comprises housing 114. Housing 114 may be a rectangular member containing electrical components necessary to convert electricity generated by solar cells 112 into frequencies and voltages compatible with apparatus contained within the building and with the building's power grid. The electrical components may comprise power regulation components, circuit breakers, communications modules, and status modules designed to provide information about the status of power generation apparatus 100 or to provide such information wirelessly (e.g., via the Internet 1006). Housing 114 may also contain hardware necessary to move cross members 110 between an open position and a closed position.

In an aspect, housing 114 contains a microinverter which converts direct current generated by solar cells 112 to alternating current, suitable for interfacing with a power grid and powering common appliances. In another aspect, the microinverter is configured to provide 240 Vac. In an aspect, the microinverter is switchable. That is, a user may change the electrical output of power generation apparatus 100.

In an aspect, housing 114 contains a communications module. Communications module may be a wired or wireless network connection (e.g., a local area network connection), an RF transceiver, a power line communication module, and the like. The communications module may facilitate providing information about the status of power generation apparatus 100 to one or more users.

Cross members 110 comprise solar cells 112 which are electrically connected to electrical components within housing 114. Each cross member 110 is movably connected to frame 102.

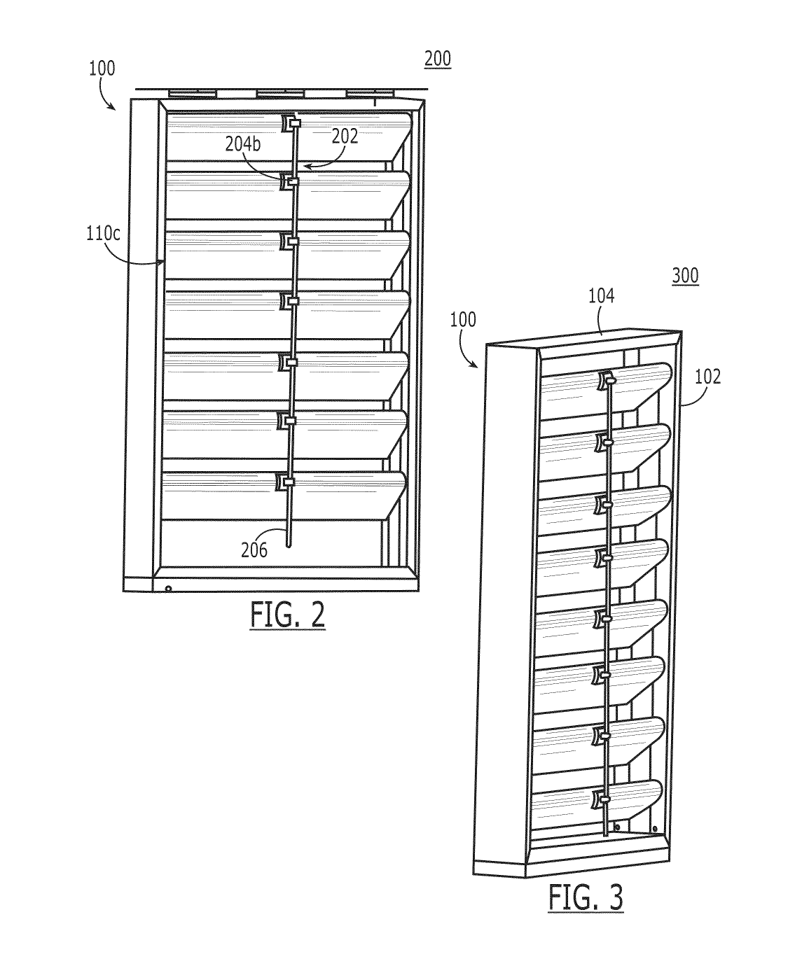

In an aspect, each cross member 110 is rotatably connected to frame 102. Each cross member 110 may rotate between a closed position and an open position. In the closed position, cross member 110 is in a position (e.g., a vertical position, an inclined position) which prevents at least some light from entering the interior of the building. In the closed position, solar cell 112 faces outward, thereby receiving sunlight which is converted into electricity. In the open position, cross member 110 has been rotated away from the building aperture. This may allow light to pass into the building. Cross members 110 may be individually or collectively moved. Movement may be done manually or with the aid of a mechanical device. The mechanical device may be contained within frame 102 or position along an exterior portion of apparatus 100, as shown in FIG. 2. Power generation apparatus 110 may comprise a pulley, rotator motors, solenoid actuator, or some other device apparent to those having skill in the art after reading the description herein suitable for moving cross members 110 from a closed position to an open position.

Solar cells 112 may be photovoltaic cells, thermoelectric cells, or other devices which convert solar energy into electricity. Photovoltaic cells suitable for use in power generation apparatus 100 may be constructed of polycrystalline, monocrystalline, or amorphous silicon. In some embodiments, the solar cells may be concentrated photovoltaic cells or organic solar cells. Solar cells 112 may be rigid or flexible. Solar cells 112 are electrically connected to electrical components in housing 114. In an aspect, solar cells 112 are photovoltaic cells which are electrically connected by wires within frame 102 to a microinverter contained within housing 114, thereby supplying a DC current which the microinverter converts to AC current suitable for powering equipment found in the building or compatible with the building's power grid (e.g., 120 Vac current, 240 Vac).

In an aspect, solar cell 112 comprises a transparent, translucent, or opaque photovoltaic cell stacked on top of a thermoelectric cell, thereby generating electricity via both devices.

In an aspect, solar cells 112 are photovoltaic cells embedded in cross members 110. Cross members 110 are the louvers of window shades. Each solar cell 112 is sandwiched between a plate of glass and a plastic backing. Solar cell 112 is connected to two bolts, or retractable pins on either side serving as electrodes so that they can be easily attached to frame 100. This connection serves as both a connection enabling rotation of cross member 110 and an electrical connection of solar cell 112. In some embodiments, Plexiglas®, plastic, wood, or metals may be used to construct cross member 110.

Power generation apparatus 100 further comprises a cable 116. Cable 116 is electrically connected to electrical components within housing 114 and comprises a power plug 118. In an aspect, power plug 118 is a three prong AC power plug suitable for inserting into power outlet 120, thereby enabling electricity generated by power generation apparatus 100 to supply electricity to the building power grid without separate, or additional equipment.

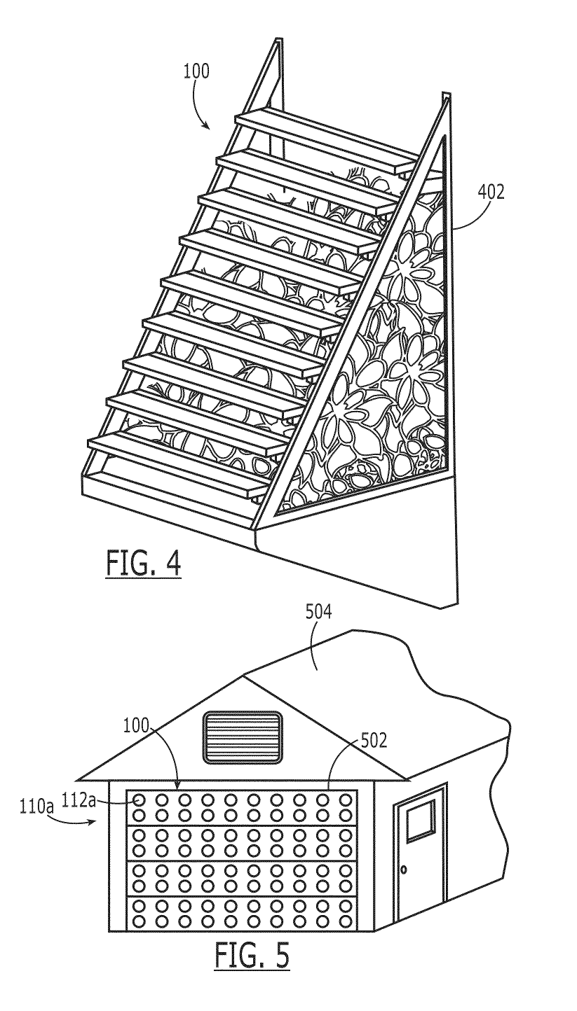

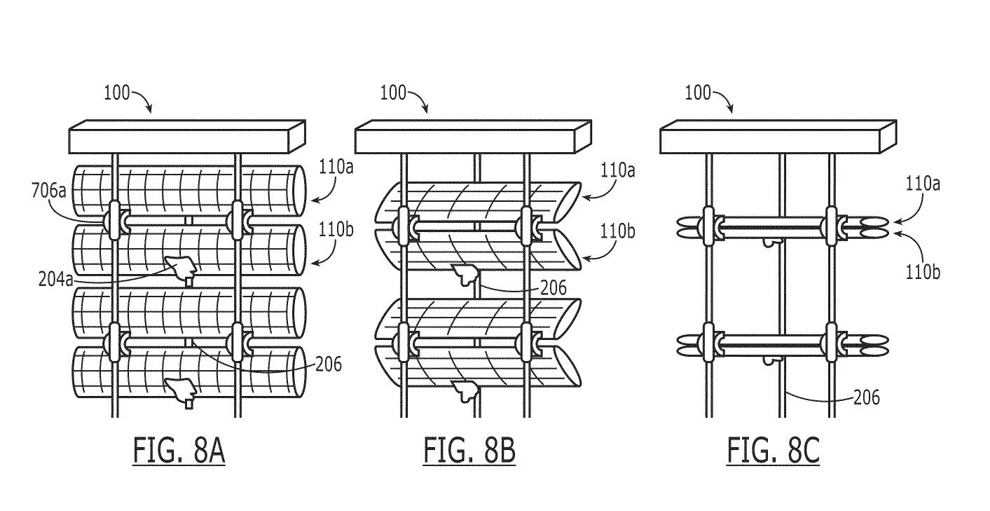

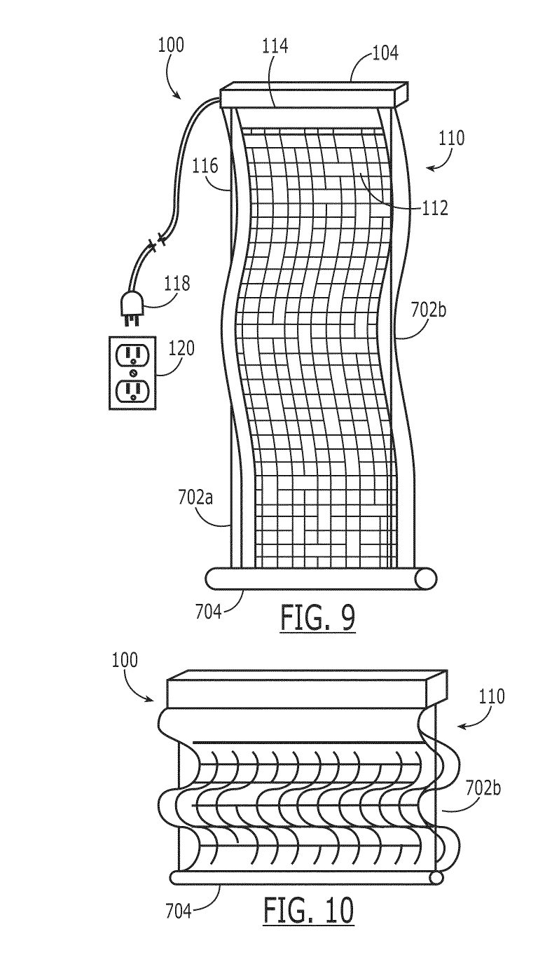

In other aspects, power generation apparatus 100 comprises solar cells 112 which roll up (as shown, for example, in FIGS. 8 and 9), fold (as shown, for example, in FIGS. 4 and 5), bend, or collapse. The modular nature of the various parts of power generation apparatus 100 allows for their use inside and outside different sized windows, garage openings, and sliding door frames.

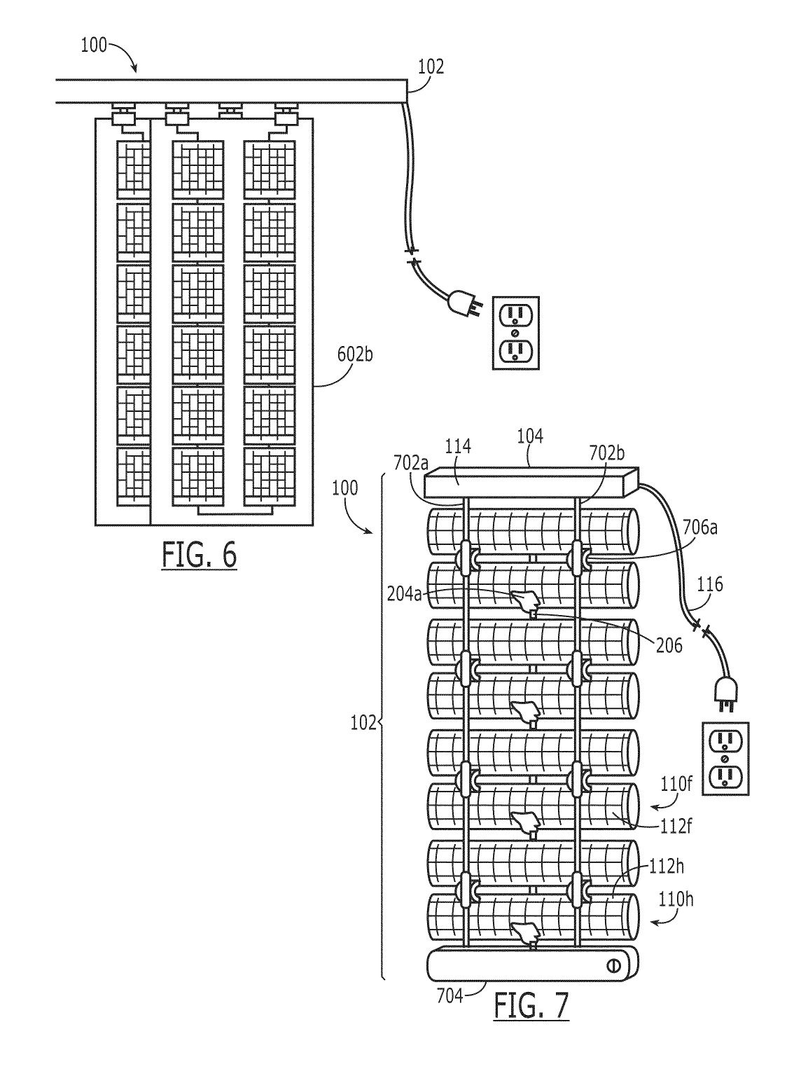

In another aspect, shown in FIG. 6, power generation apparatus 100 uses amorphous, flexible, window shades or rigid panels 602 (labeled, for clarity, only as panel 602b in FIG. 6) like sliding doors capable of sliding over a rail located on the top or bottom of frame 102 by means of wheels, pulleys, or ball bearings and with the rail providing the means to slide the window shade like traditional curtain window shades while maintaining an electrical circuit at all times with the use of wires, or metal wheels that roll over a conductive track which in turn is connected to a microinverter contained within power generation apparatus 100. Such panels 602 may comprise silicon, copper indium gallium selenide (CIGS), or Cadmium telluride (CdTe).

In an aspect, power generation apparatus 100 may comprise a break. Furthermore, power generation apparatus 100 may be configured to be removed from a building aperture by laymen in the event of an emergency (e.g., a fire).

In an aspect, power generation apparatus 100 may be mounted on the side of a structure to serve as an awning.

Power generation apparatus 100 may also comprise motors that, in case of an emergency or user command, can rotate the window treatment 90°, open the window, or retract the garage door apparatus. In an emergency, this enables egress from the building via the aperture. Such a configuration also allows power generation apparatus 100 to be mounted on the side of a structure to serve as a retractable awning. In another aspect, such a configuration may be mounted over a window and operate as a Bahama shutter.

In alternative aspects, power generation apparatus 100 may be constructed to incorporate different designs and styles placed on the interior or exterior sides of power generation apparatus 100 to provide aesthetic appeal to the décor. Additional designs may incorporate flat power cables to blend in with the existing décor. Other aspects may have LED lights incorporated as a means to provide additional interior or exterior light. Cross members 110 may also have lenses, mirrors or reflective films to magnify radiant light onto the enclosed solar cells. Aspects may be designed with electronics and various shapes to embody a greenhouse for example when mounted on the outside of a window. Suction cups and other mounting equipment may be used to attach power generation apparatus 100 to windows. Some aspects may allow for the swivel, rotation, or pivoting of cross members 110 at a 90° angle on a vertical or horizontal axis.

Referring now to FIG. 2, a rear view of power generation apparatus 100 configured to be placed adjacent to a building window wherein power generation apparatus 100 comprises a manual mechanism 202 for altering the positioning of cross members 110 (labeled, for clarity, only as cross member 110c in FIG. 2), according to an aspect of the present disclosure, is shown.

Cross members 110 may be manually moved in unison via rotation mechanism 202. Rotation mechanism 202 comprises links 204 (labeled, for clarity, only as link 204b in FIG. 2) and rod 206. Each link 204 is connected to one cross member 110. Rod 206 and links 204 are connected, thereby allowing a user to move rod 204 up or down and rotate cross members 110 from a closed position to an open position and vice versa.

Referring briefly now to FIG. 3, a rear perspective view of power generation apparatus 100 configured to be placed adjacent to a building window, wherein frame 102 and the mounting plate 104 have been removably connected, according to an aspect of the present disclosure, is shown.

Referring now to FIG. 4, a front perspective view of power generation apparatus 100 which has been integrated into the roof of a planter 402, according to an aspect of the present disclosure, is shown.

Power generation apparatus 100 may be configured to operate as a portion of a structure. For example, planter 402 may be attached to a larger building, such as a house. The roof of planter 402 may be power generation apparatus 100. In this aspect, electricity generated by power generation apparatus 100 may be utilized by planter 402 to operate equipment within planter 402 (e.g., a sprinkler system, growing lights) or may be connected to the building's power grid in order to provide electricity.

Referring now to FIG. 5, a front view of power generation apparatus 100 which may also serve as a garage door 502, according to an aspect of the present disclosure, is shown.

Power generation apparatus 100 may form garage door 502 of a house 504. Frame 102 may comprise garage door 502. In this aspect, cross member 110 is a hinged panel of garage door 502. Solar cells 112 capture radiant energy when garage door 502 is closed.

Referring now to FIG. 7, a front perspective view of onsite solar power generation apparatus 100 configured to be placed adjacent to a building window, according to an aspect of the present disclosure, is shown.

In an aspect, power generation apparatus 100 comprises cross members 110 which open and close in a clam shell fashion, as shown in FIGS. 8A-C. The top horizontal portion of frame 102 is housing 114. Housing 114 is configured to connect to mount 104. Frame 102 further comprises vertical members 702. Vertical members comprise vertical connectors 706 (labeled, for clarity, only as vertical connector 706a in FIG. 7) which rotatably connect cross members 110 to frame 100 and provide an electrical connection. Frame bottom portion 704 is a horizontal member which may be connected to the building.

Referring now to FIGS. 9 and 10, a front perspective view of onsite solar power generation apparatus 100 configured to be placed adjacent to a building window, according to an aspect of the present disclosure, are shown.

In another aspect, cross member 110 is flexible and houses a flexible solar cell 112. Solar cell 112 is a flexible photovoltaic cell. Vertical member 702 is retractable and frame bottom portion 604 is movable, thereby enabling movement of cross member 110 from an extended, closed position (FIG. 9) to a retracted, open position (FIG. 10). Power generation apparatus 100 may be rolled up or deployed using a pull string arrangement.

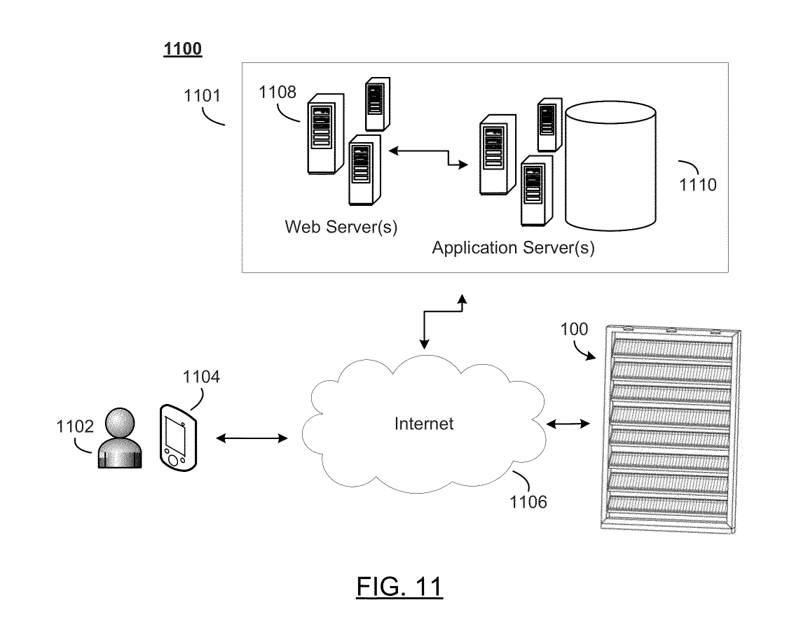

Referring now to FIG. 11, a block diagram of an exemplary system 1100 for accessing information regarding an onsite solar power generation apparatus, according to an aspect of the present disclosure, is shown.

Cloud-based, Internet-enabled communication system 1100 may include one or more users 1102 accessing—via a computing device 1104 and a network 1106, such as the global, public Internet—an application service provider's cloud-based, Internet-enabled infrastructure 1101. One or more of users 1102 may access infrastructure 1101 in order to receive information about the status of power generation apparatus 100 (e.g., current power generation, historical power generation, connection status to a local grid), cause power generation apparatus 100 to perform a function (e.g., move cross members 110 from one position to another), and the like.

As shown in FIG. 11, in an aspect of the present disclosure, an application service provider's cloud-based, communications infrastructure 1101 may include one or more web servers 1108 and one or more application servers 1110.

As will be appreciated by those skilled in the relevant art(s) after reading the description herein, in such an aspect, an application service provider—an individual person, business, or other entity—may allow access, on a free registration, paid subscriber and/or pay-per-use basis, to infrastructure 1101 via one or more World-Wide Web (WWW) sites on the Internet 1106. Thus, system 1100 is scalable.

As will also be appreciated by those skilled in the relevant art(s), in an aspect, various screens would be generated by web server 1108 in response to input from users 1102 over Internet 1106. That is, in such an aspect, server 1108 is a typical web server running a server application at a website which sends out webpages, while in communications with server 1110, in response to Hypertext Transfer Protocol (HTTP) or Hypertext Transfer Protocol Secured (HTTPS) requests from remote browsers on computing devices being used by various users 1102. Thus, server 1108 is able to provide a graphical user interface (GUI) in the form of, for example, webpages or other screens. These webpages are sent to the associated computing devices 1104, and would result in the GUI being displayed.

In alternate aspects, application servers 1110 (shown with associated storage in FIG. 11) may be configured to store various modules and data associated with one or more apparatus 100 and one or more users 1102. In alternate aspects, application servers 1110 may comprise one or more data stores within (or remotely located from) infrastructure 1101 or be a memory included in (or coupled to) web server(s) 1108. That is, in alternate aspects, web servers 1108 and application servers 1110 may be located on the same physical machines as will be appreciated by those skilled in the relevant art(s) after reading the description herein.

As will be appreciated by those skilled in the relevant art(s) after reading the description herein, alternate aspects of the present disclosure may include providing infrastructure 1001 as a stand-alone system (e.g., installed on one server PC) or as an enterprise system wherein all the components of infrastructure 1000 are connected and communicate via an inter-corporate Wide Area Network (WAN) or Local Area Network (LAN).

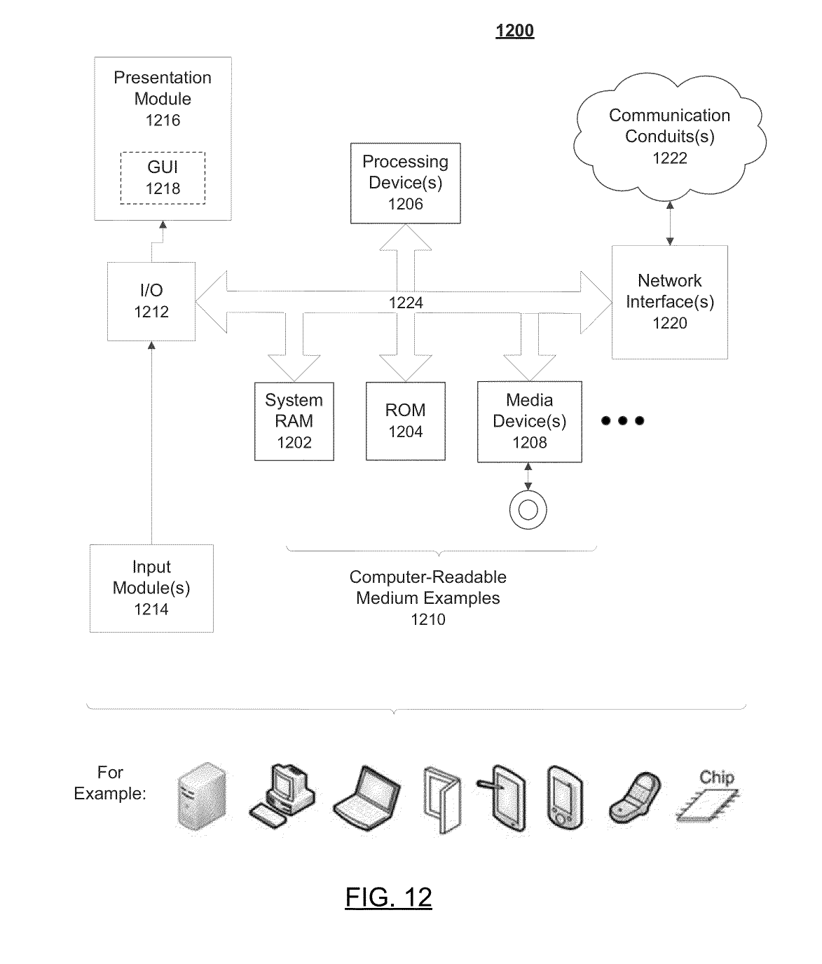

Referring now to FIG. 12, a block diagram of an exemplary computer system useful for implementing various aspects the systems and apparatus disclosed herein, in accordance with one or more aspects of the present disclosure, is shown.

That is, FIG. 12 sets forth illustrative computing functionality 1200 that may be used to implement web server 1108, one or more application servers 1110, computing devices utilized by user 1102, to access Internet 1106 in order to access information or otherwise interact with power generation apparatus 100. In all cases, computing functionality 1200 represents one or more physical and tangible processing mechanisms.

Computing functionality 1200 may comprise volatile and non-volatile memory, such as RAM 1202 and ROM 1204, as well as one or more processing devices 1206 (e.g., one or more central processing units (CPUs), one or more graphical processing units (GPUs), and the like). Computing functionality 1200 also optionally comprises various media devices 1208, such as a hard disk module, an optical disk module, and so forth. Computing functionality 1200 may perform various operations identified above when the processing device(s) 1206 executes instructions that are maintained by memory (e.g., RAM 1202, ROM 1204, and the like).

More generally, instructions and other information may be stored on any computer readable medium 1210, including, but not limited to, static memory storage devices, magnetic storage devices, and optical storage devices. The term “computer readable medium” also encompasses plural storage devices. In all cases, computer readable medium 1210 represents some form of physical and tangible entity. By way of example, and not limitation, computer readable medium 1210 may comprise “computer storage media” and “communications media.”

“Computer storage media” comprises volatile and non-volatile, removable and non-removable media implemented in any method or technology for storage of information, such as computer readable instructions, data structures, program modules or other data. Computer storage media may be, for example, and not limitation, RAM 1202, ROM 1204, EEPROM, Flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by a computer.

“Communication media” typically comprise computer readable instructions, data structures, program modules, or other data in a modulated data signal, such as carrier wave or other transport mechanism. Communication media may also comprise any information delivery media. The term “modulated data signal” means a signal that has one or more of its characteristics set or changed in such a manner as to encode information in the signal. By way of example, and not limitation, communication media comprises wired media such as a wired network or direct-wired connection, and wireless media such as acoustic, RF, infrared, and other wireless media. Combinations of any of the above are also included within the scope of computer readable medium.

Computing functionality 1200 may also comprise an input/output module 1212 for receiving various inputs (via input modules 1214), and for providing various outputs (via one or more output modules). One particular output mechanism may be a presentation module 1216 and an associated GUI 1218. Computing functionality 1200 may also include one or more network interfaces 1220 for exchanging data with other devices via one or more communication conduits 1222. In some aspects, one or more communication buses 1224 communicatively couple the above-described components together.

Communication conduit(s) 1222 may be implemented in any manner (e.g., by a local area network, a wide area network (e.g., the Internet 1106), and the like, or any combination thereof). Communication conduit(s) 1222 may include any combination of hardwired links, wireless links, routers, gateway functionality, name servers, and the like, governed by any protocol or combination of protocols.

Alternatively, or in addition, any of the functions described herein may be performed, at least in part, by one or more hardware logic components. For example, without limitation, illustrative types of hardware logic components that may be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

The terms “service,” “module” and “component” as used herein generally represent software, firmware, hardware or combinations thereof. In the case of a software implementation, the service, module or component represents program code that performs specified tasks when executed on one or more processors. The program code may be stored in one or more computer readable memory devices, as described with reference to FIG. 12. The features of the present disclosure described herein are platform-independent, meaning that the techniques can be implemented on a variety of commercial computing platforms having a variety of processors (e.g., desktop, laptop, notebook, tablet computer, personal digital assistant (PDA), mobile telephone, smart telephone, gaming console, and the like).

While various aspects of the present disclosure have been described above, it should be understood that they have been presented by way of example and not limitation. It will be apparent to persons skilled in the relevant art(s) that various changes in form and detail can be made therein without departing from the spirit and scope of the present disclosure. Thus, the present disclosure should not be limited by any of the above described exemplary aspects, but should be defined only in accordance with the following claims and their equivalents.

In addition, it should be understood that the figures in the attachments, which highlight the structure, methodology, functionality and advantages of the present disclosure, are presented for example purposes only. The present disclosure is sufficiently flexible and configurable, such that it may be implemented in ways other than that shown in the accompanying figures (e.g., implementation within other static or mobile structures or portions of such structures). As will be appreciated by those skilled in the relevant art(s) after reading the description herein, certain features from different aspects of the systems, methods and computer program products of the present disclosure may be combined to form yet new aspects of the present disclosure.

Further, the purpose of the foregoing Abstract is to enable the U.S. Patent and Trademark Office and the public generally and especially the scientists, engineers and practitioners in the relevant art(s) who are not familiar with patent or legal terms or phraseology, to determine quickly from a cursory inspection the nature and essence of this technical disclosure. The Abstract is not intended to be limiting as to the scope of the present disclosure in any way.

What is claimed is:

1. An onsite solar power generation apparatus configured to augment electrical power within a structure and movably block sunlight, comprising:
a plurality of cross members movable between a closed position which prevents sunlight from entering a building and an open position which allows sunlight to enter the building;
a plurality of solar cells positioned on the plurality of cross members;
a frame configured to support the plurality of cross members and configured to mount to a surface of a building adjacent to a building aperture and position the plurality of solar cells to receive sun light, the frame comprising:
a housing containing a conversion component, the conversion component electrically connected to each of the plurality of solar cells and configured to convert electricity generated by the plurality of solar cells into electricity suitable for utilization in the building; and
a power connection configured to provide electricity converted by the conversion component to a building power grid.

2. The onsite solar power generation apparatus of claim 1, wherein the conversion component comprises a microinverter.

3. The onsite solar power generation apparatus of claim 1, wherein the conversion component and the power connection are configured to provide electricity to a building power grid.

4. The onsite solar power generation apparatus of claim 1, wherein the conversion component and the power connection are configured to provide electricity to an alternating current appliance.

5. The onsite solar power generation apparatus of claim 1, wherein, in the closed position, the plurality of solar cells is exposed to sunlight and, in the open position, the plurality of solar cells does not receive sunlight.

6. The onsite solar power generation apparatus of claim 1, wherein the building aperture is one of: a window; a door; and a garage door opening.

7. The onsite solar power generation apparatus of claim 1, wherein the frame is configured as a garage door and each of the plurality of cross members is a garage door panel.

8. The onsite solar power generation apparatus of claim 1, wherein the onsite solar power generation apparatus is configured as a planter roof.

9. The onsite solar power generation apparatus of claim 1, wherein:
each of the plurality of cross members is vertically oriented; and
each of the vertical cross members rotate between the closed position and the open position along a vertical rotation axis.

10. The onsite solar power generation apparatus of claim 1, wherein each of the plurality of cross members is horizontally oriented and horizontally rotates between the closed position and the open position.

11. The onsite solar power generation apparatus of claim 1, further comprising:
a rotation mechanism rotatably attached to each of the plurality of cross members, the rotation mechanism configured to move the plurality of cross members between the closed position and the open position.

12. The onsite solar power generation apparatus of claim 1, wherein each of plurality of solar cells are photovoltaic members.

13. The onsite solar power generation apparatus of claim 1, wherein each of plurality of solar cells are one of: a photovoltaic member and a thermoelectric member.

14. The onsite solar power generation apparatus of claim 1, further comprising:
a network connection;
a communications module; and
a reporting module configured to report status of the onsite solar power generation apparatus to a user via the communications module and the network connection.

15. The onsite solar power generation apparatus of claim 1, wherein each of the plurality of cross members are flexible.

16. The onsite solar power generation apparatus of claim 1, wherein the power connection comprises an AC power plug.

17. The onsite solar power generation apparatus of claim 16, wherein the AC power plug is one of: a Type A connection and a Type B connection.

18. The onsite solar power generation apparatus of claim 1, wherein the onsite solar power generation apparatus is configured to provide 120 Vac power via the power connection.

19. An onsite solar power generation apparatus configured to augment electrical power within a structure and movably block sunlight, comprising:
a plurality of horizontally oriented cross members configured as window shade louvers, movable between a closed position which prevents sunlight from entering a building and an open position which allows sunlight to enter the building;
a plurality of solar cells positioned on the plurality of cross members;
a frame configured to support the plurality of cross members and configured to mount to a surface of a building adjacent to a building window and position the plurality of solar cells to receive sun light, the frame comprising:
a housing containing a microinverter, the microinverter electrically connected to each of the plurality of solar cells and configured to convert electricity generated by the plurality of solar cells into electricity suitable for utilization in the building;
a rotation mechanism rotatably attached to each of the plurality of cross members, the rotation mechanism configured to move the plurality of cross members between the closed position and the open position; and
a power connection configured to provide electricity converted by the microinverter to a building power grid via an AC power plug.

20. An onsite solar power generation apparatus configured to augment electrical power within a structure and movably block sunlight, comprising:
a plurality of horizontally oriented cross members configured as window shade louvers, movable between a closed position which prevents sunlight from entering a building and an open position which allows sunlight to enter the building;
a plurality of solar cells positioned on the plurality of cross members;
a frame configured to support the plurality of cross members and configured to mount to a surface of a building adjacent to a building window and position the plurality of solar cells to receive sun light, the frame comprising:
a housing containing a microinverter, the microinverter electrically connected to each of the plurality of solar cells and configured to convert electricity generated by the plurality of solar cells into electricity suitable for utilization in the building;
a rotation mechanism rotatably attached to each of the plurality of cross members, the rotation mechanism configured to move the plurality of cross members between the closed position and the open position;
a network connection;
a communications module;
a reporting module configured to report status of the onsite solar power generation apparatus to a user via the communications module and the network connection; and
a power connection configured to provide electricity converted by the microinverter to a building power grid via an AC power plug.
